(19) United States
(12) Patent Application Publication
(10) Pub. No.: US 2026/0092195 A1
(43) Pub. Date: Apr. 2, 2026

(54) POLISHING COMPOSITION

(71) Applicant: FUJIMI INCORPORATED, Aichi (JP)

(72) Inventors: Atsushi Tsuzuki, Aichi (JP); Masashi Abe, Aichi (JP)

(21) Appl. No.: 19/325,654

(22) Filed: Sep. 11, 2025

(30) Foreign Application Priority Data
Sep. 27, 2024 (JP) 2024-168525

(51) Int. Cl. C09G 1/02; B24B 37/04; C09K 3/14; H01L 21/3105

(52) U.S. Cl. CPC C09G 1/02; B24B 37/044; C09K 3/1409; H10P 95/062

(57) ABSTRACT

Provided is a polishing composition that can polish a carbon film at a high polishing removal rate. A polishing composition containing abrasive grains and a nonionic surfactant, wherein the polishing composition is used for polishing an object to be polished containing a carbon film.

### TECHNICAL FIELD

The present invention relates to a polishing composition.

### BACKGROUND ART

In recent years, due to the multilayered wiring of the surface of a semiconductor substrate, a technology known as Chemical Mechanical Polishing (CMP) technology in which a semiconductor substrate is polished to be flattened at the time of producing a device has been used. CMP is a method in which the surface of an object to be polished such as a semiconductor substrate is flattened by using a polishing composition.

Studies have been continued in the field of the CMP technology in order to achieve a desired effect by polishing.

Japanese Patent Laid-Open No. 2024-092301 discloses that, on a substrate containing silicon oxide and silicon nitride, both silicon oxide and silicon nitride can be polished at a high polishing removal rate with a polishing composition having a specific particle size distribution and containing an inorganic particle having an organic acid immobilized on the surface thereof and an acid compound. Japanese Patent Laid-Open No. 2024-092301 discloses that an object to be polished contains a carbon film.

### SUMMARY OF INVENTION

According to the technology described in Japanese Patent Laid-Open No. 2024-092301, a silicon oxide film and a silicon nitride film can be polished at a high polishing removal rate. However, there has been room for improvement of the polishing removal rate of a carbon film.

An object of the present invention is to provide a polishing composition that can polish a carbon film at a high polishing removal rate.

In order to achieve the object, the present inventors have conducted intensive studies. As a result, they have found the fact that the object can be achieved with a polishing composition containing abrasive grains and a nonionic surfactant, wherein the polishing composition is used for polishing an object to be polished containing a carbon film, thereby achieving the present invention.

### DESCRIPTION OF EMBODIMENTS

Embodiments of the present invention will hereinafter be described, but the present invention is not limited to the embodiments described below, and various modifications could be made within the scope of the claims. The embodiments described in the present specification could be arbitrarily combined for another embodiment. In the present specification, unless otherwise specified, operations and measurements of physical properties and the like are performed under the conditions of room temperature (20° C. or more and 25° C. or less)/a relative humidity of 40% RH or more and 50% RH or less.

### <Polishing Composition>

An aspect of the present invention relates to a polishing composition containing abrasive grains and a nonionic surfactant, wherein the polishing composition is used for polishing an object to be polished containing a carbon film. The polishing composition according to the present invention can polish the carbon film at a high polishing removal rate.

### [Abrasive Grains]

The polishing composition according to the present invention contains abrasive grains.

The type of the abrasive grains is not particularly limited, and examples thereof include metal oxides such as silica, alumina, zirconia, and titania. As the abrasive grains, one type thereof may be used alone, or two or more types thereof may be used in combination. As the abrasive grains, a commercially available product may be used, or a synthesized product may be used.

In an embodiment, the abrasive grains contain a silica, and preferably contain a colloidal silica. Examples of the method for producing the colloidal silica include a sodium silicate method and a sol-gel method, and a colloidal silica produced by any production method can be suitably used as the abrasive grains of the present invention. However, from the viewpoint of reducing metal impurities, a colloidal silica produced by a sol-gel method, in which production at high purity is possible, may be preferred.

Production of the colloidal silica by a sol-gel method may be performed by using a conventionally known method. Specifically, the colloidal silica can be obtained by performing hydrolysis condensation reaction using a hydrolysable silicon compound (for example, alkoxysilane or a derivative thereof) as a raw material.

In a preferred embodiment, the abrasive grains contain an anion-modified colloidal silica (colloidal silica having an anionic group). Examples of the anion-modified colloidal silica include a colloidal silica having an anionic group such as a carboxylic acid group, a sulfonic acid group, a phosphonic acid group, and an aluminate group immobilized on the surface thereof.

The method for producing the anion-modified colloidal silica is not particularly limited, and examples thereof include a method in which a silane coupling agent having an anionic group on the terminal thereof and the colloidal silica are allowed to react with each other.

Specific examples of the method for immobilizing the sulfonic acid group on the colloidal silica include a method described in “Sulfonic acid-functionalized silica through quantitative oxidation of thiol groups”, Chem. Commun. 246-247 (2003). Specifically, a colloidal silica having a sulfonic acid group immobilized on the surface thereof (sulfonic acid-modified colloidal silica) can be obtained by coupling a silane coupling agent having a thiol group such as 3-mercaptopropyltrimethoxysilane to the colloidal silica, and then oxidizing the thiol group with hydrogen peroxide.

Examples of the method for immobilizing the carboxylic acid group on the colloidal silica include a method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, a colloidal silica having a carboxylic acid group immobilized on the surface thereof (carboxylic acid-modified colloidal silica) can be obtained by coupling a silane coupling agent containing photoreactive 2-nitrobenzyl ester to the colloidal silica, and then irradiating light thereon.

The average primary particle size of the abrasive grain is not particularly limited, but is preferably 1 nm or more, more preferably 3 nm or more, and further preferably 5 nm or more. The average primary particle size of the abrasive grain is not particularly limited, but is preferably 100 nm or less, more preferably 50 nm or less, and further preferably 30 nm or less. Examples of the preferred average primary particle size of the abrasive grain include 1 nm or more and 100 nm or less, 3 nm or more and 50 nm or less, and 5 nm or more and 30 nm or less. However, the average primary particle size of the abrasive grain is not limited to these ranges. Where the abrasive grain is an anion-modified colloidal silica, the preferred range of the average primary particle size of the anion-modified colloidal silica is the same as the preferred range of the average primary particle size of the abrasive grain as described above. The average primary particle size of the abrasive grain can be calculated based on the specific surface area (SA) of the abrasive grain calculated by the BET method and the density of the abrasive grain. More specifically, the average primary particle size of the abrasive grain can be measured and calculated by the method described in Examples.

The average secondary particle size of the abrasive grain is not particularly limited, but is preferably 15 nm or more, more preferably 20 nm or more, and further preferably 25 nm or more. If the average secondary particle size is within the above range, the resistance during polishing is small, thereby allowing for stable polishing. The average secondary particle size of the abrasive grain is not particularly limited, but is preferably 500 nm or less, more preferably 400 nm or less, and further preferably 300 nm or less. If the average secondary particle size is within the above range, the removal amount of the object to be polished is enhanced, thereby enhancing the polishing removal rate. Examples of the preferred average secondary particle size of the abrasive grain include 15 nm or more and 500 nm or less, 20 nm or more and 400 nm or less, and 25 nm or more and 300 nm or less. However, the average secondary particle size of the abrasive grain is not limited to these ranges. Where the abrasive grain is an anion-modified colloidal silica, the preferred range of the average secondary particle size of the anion-modified colloidal silica is the same as the preferred range of the average secondary particle size of the abrasive grain as described above. The average secondary particle size of the abrasive grain can be measured as a volume-average particle size (arithmetic mean size on volume basis; Mv) by a dynamic light scattering method. More specifically, the average secondary particle size of the abrasive grain can be measured by the method described in Examples.

The ratio of the average secondary particle size to the average primary particle size of the abrasive grains (Average secondary particle size/Average primary particle size) (hereinafter, “the ratio of the average secondary particle size to the average primary particle size” is also referred to as “average degree of association”) is not particularly limited, but is preferably more than 1.0, more preferably 1.1 or more, and further preferably 1.2 or more. The average degree of association of the abrasive grains is not particularly limited, but is preferably 4.0 or less, more preferably 3.5 or less, and further preferably 3.0 or less. Examples of the preferred average degree of association of the abrasive grains include more than 1.0 and 4.0 or less, 1.1 or more and 3.5 or less, and 1.2 or more and 3.0 or less. However, the average degree of association of the abrasive grains is not limited to these ranges. Where the abrasive grains contain an anion-modified colloidal silica, the preferred range of the average degree of association of the anion-modified colloidal silica is the same as the preferred range of the average degree of association of the abrasive grains as described above. The average degree of association of the abrasive grains can be calculated by dividing the value of the average secondary particle size of the abrasive grains by the value of the average primary particle size of the abrasive grains (Value of average secondary particle size of abrasive grains/Value of average primary particle size of abrasive grains).

The shape of the abrasive grain (preferably anion-modified colloidal silica) is not particularly limited, and the shape may be spherical or non-spherical. Specific examples of the non-spherical shape include various shapes such as a polygonal shape such as a triangular prism and a quadrangular prism, a cylindrical shape, a barrel-like shape in which the central part of a column is bulged compared with the end part, a doughnut-like shape in which the central part of a disk is penetrated, a plate-like shape, a shape known as a cocoon-like shape having a constriction in the central part, a shape known as an aggregated-type spherical shape in which a plurality of particles are aggregated into a single body, a shape known as a kompeito-like shape having a plurality of protrusions on the surface, and a rugby ball-like shape, which are not particularly limited.

Each of the shape and the size (the average primary particle size, the average secondary particle size, the average degree of association, and the like) of the abrasive grain can be appropriately controlled by, for example, selection of the method for producing the abrasive grain. However, the method for controlling each of the shape and the size of the abrasive grain is not limited thereto.

The content (concentration) of the abrasive grains (preferably anion-modified colloidal silica) in the polishing composition is not particularly limited, but is preferably 0.01 mass % or more, more preferably 0.05 mass % or more, further preferably 0.1 mass % or more, and particularly preferably 0.3 mass % or more based on the total mass of the polishing composition. The content of the abrasive grain (preferably anion-modified colloidal silica) in the polishing composition is not particularly limited, but is preferably 10 mass % or less, more preferably 5 mass % or less, further preferably 2 mass % or less, and particularly preferably 1 mass % or less based on the total mass of the polishing composition. If the content is within the above range, the polishing removal rate at the time of polishing a specific object to be polished is enhanced more. Also, if the content is within the above range, a selectivity for a specific object to be polished with respect to another specific object to be polished is sometimes enhanced more. The preferred content of the abrasive grain (preferably anion-modified colloidal silica) in the polishing composition is not particularly limited, but examples thereof include 0.01 mass % or more and 10 mass % or less, 0.05 mass % or more and 5 mass % or less, 0.1 mass % or more and 2 mass % or less, and 0.3 mass % or more and 1 mass % or less based on the total mass of the polishing composition. However, the content of the abrasive grain in the polishing composition is not limited to these ranges.

### [Nonionic Surfactant]

The polishing composition according to the present invention contains a nonionic surfactant. As the nonionic surfactant, one type thereof may be used alone, or two or more types thereof may be used in combination. As the nonionic surfactant, a commercially available product may be used, or a synthesized product may be used.

The nonionic surfactant can be adsorbed on the surface of the hydrophobic carbon film to hydrophilize the surface of the carbon film. It is considered that the hydrophilized surface of the carbon film increases in the frequency of contact as a result of interaction between the surface of the carbon film and the abrasive grain (for example, anion-modified colloidal silica), thereby enhancing the polishing removal rate of the carbon film.

Examples of the nonionic surfactant include alkyl betaines, alkyl amine oxides, polyoxyalkylene glycols, polyoxyalkylene alkyl ethers, sorbitan fatty acid esters, glycerol fatty acid esters, polyoxyalkylene fatty acid esters, polyoxyalkylene alkyl amines, and alkyl alkanolamides. The nonionic surfactant is preferably a compound having a polyoxyalkylene glycol structure (also referred to as “polyoxyalkylene glycol compound” in the present specification) such as polyoxyalkylene glycol and polyoxyalkylene alkyl ether from the viewpoint that the effect of the present invention can be more effectively exerted.

In a preferred embodiment, the nonionic surfactant contains a compound having a polyoxyalkylene glycol structure. Examples of the compound having a polyoxyalkylene glycol structure include oxyalkylene homopolymers, oxyalkylene copolymers, and polyoxyalkylene alkyl ethers.

The oxyalkylene homopolymers and the oxyalkylene copolymers are not particularly limited, and examples thereof include polyethylene glycol, polypropylene glycol, polyethylene glycol-polypropylene glycol random copolymers, polyethylene glycol-polytetramethylene glycol random copolymers, polypropylene glycol-polytetramethylene glycol random copolymers, polyethylene glycol-polypropylene glycol-polytetramethylene glycol random copolymers, polyethylene glycol-polypropylene glycol block copolymers, polypropylene glycol-polyethylene glycol-polypropylene glycol triblock copolymers, and polyethylene glycol-polypropylene glycol-polyethylene glycol triblock copolymers.

In a more preferred embodiment, the nonionic surfactant contains a compound represented by the following formula 1 as polyoxyalkylene alkyl ether.

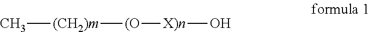

Wherein X is an alkylene group having 2 or 3 carbon atoms; m is an integer of 4 or more and 14 or less; and n is an integer of 3 or more and 25 or less.

In the formula 1, X is preferably an alkylene group having 2 carbon atoms (that is, an ethylene group).

In the formula 1, m is preferably an integer of 5 or more and 12 or less, and more preferably an integer of 7 or more and 9 or less.

In the formula 1, n is preferably an integer of 5 or more and 15 or less, and more preferably an integer of 5 or more and 10 or less.

The compound represented by the formula 1 is preferably at least one selected from the group consisting of polyoxyethylene (5) monooctyl ether, polyoxyethylene (6) monooctyl ether, polyoxyethylene (7) monooctyl ether, polyoxyethylene (8) monooctyl ether, polyoxyethylene (9) monooctyl ether, polyoxyethylene (10) monooctyl ether, polyoxyethylene (5) monononyl ether, polyoxyethylene (6) monononyl ether, polyoxyethylene (7) monononyl ether, polyoxyethylene (8) monononyl ether, polyoxyethylene (9) monononyl ether, polyoxyethylene (10) monononyl ether, polyoxyethylene (5) monodecyl ether, polyoxyethylene (6) monodecyl ether, polyoxyethylene (7) monodecyl ether, polyoxyethylene (8) monodecyl ether, polyoxyethylene (9) monodecyl ether, and polyoxyethylene (10) monodecyl ether.

The content (concentration) of the nonionic surfactant in the polishing composition is not particularly limited, but is preferably 0.001 mass % or more, more preferably 0.005 mass % or more, and further preferably 0.01 mass % or more based on the total mass of the polishing composition. The content (concentration) of the nonionic surfactant in the polishing composition is preferably 1 mass % or less, more preferably 0.5 mass % or less, and further preferably 0.1 mass % or less based on the total mass of the polishing composition. The preferred content (concentration) of the nonionic surfactant in the polishing composition is not particularly limited, but examples thereof include 0.001 mass % or more and 1 mass % or less, 0.005 mass % or more and 0.5 mass % or less, and 0.01 mass % or more and 0.1 mass % or less based on the total mass of the polishing composition. In a preferred embodiment, the content (concentration) of the nonionic surfactant in the polishing composition is 0.01 mass % or more and 0.1 mass % or less based on the total mass of the polishing composition. However, the content (concentration) of the nonionic surfactant in the polishing composition is not limited to these ranges. If the content (concentration) of the nonionic surfactant is within the above range, the effect of the present invention can be more effectively exerted.

### [Object to be Polished]

The polishing composition according to the present invention is used for polishing an object to be polished containing a carbon film.

In the present specification, the carbon film is not limited to a film composed of a carbon simple substance, and encompasses carbon films containing atoms other than a carbon atom (such as a hydrogen atom and an oxygen atom).

Examples of the carbon film include spin-on carbon films, amorphous carbon films, diamond-like carbon films, nanocrystalline diamond films, graphene films, SiC films, and SiOC films. As the carbon film, one type thereof may be used alone, or two or more types thereof may be used in combination. The carbon film is preferably selected from the group consisting of spin-on carbon films, amorphous carbon films, diamond-like carbon films, nanocrystalline diamond films, and graphene films, and more preferably the carbon film is a spin-on carbon film.

The preferred content of carbon atoms in the carbon film is 10 mass % or more, 30 mass % or more, 50 mass % or more, 60 mass % or more, 70 mass % or more, 80 mass % or more, 90 mass % or more, 92 mass % or more, 95 mass % or more, 97 mass % or more, 98 mass % or more, and 99 mass % or more based on the total mass of the carbon film, and among these percentages, the larger one is more preferable. The carbon film may be in the form of being substantially composed of carbon (that is, in the form in which the content of carbon atoms is substantially 100 mass %).

The carbon film can be formed by CVD, PVD, a spin coating method, or the like.

The object to be polished that the polishing composition according to the present invention is to polish may further contain other materials in addition to the carbon film. Examples of other materials include a silicon nitride film, silicon oxide, single-crystalline silicon, polycrystalline silicon (polysilicon), non-crystalline silicon (amorphous silicon), polycrystalline silicon doped with n-type or p-type impurities, non-crystalline silicon doped with n-type or p-type impurities, titanium nitride, metal simple substances, and SiGe.

Examples of the object to be polished containing silicon oxide include a TEOS (Tetraethyl Orthosilicate) type silicon oxide film (hereinafter also referred to as “TEOS” or “TEOS film”) formed by using tetraethyl orthosilicate as a precursor, an HDP (High Density Plasma) film, a USG (Undoped Silicate Glass) film, a PSG (Phosphorus Silicate Glass) film, a BPSG (Boron-Phospho Silicate Glass) film, and an RTO (Rapid Thermal Oxidation) film.

Examples of the metal simple substance include tungsten, copper, cobalt, hafnium, nickel, gold, silver, platinum, palladium, rhodium, ruthenium, iridium, and osmium.

[pH]

The pH of the polishing composition according to the present invention is not particularly limited. The pH of the polishing composition according to the present invention is 1.0 or more and 5.0 or less from the viewpoint that the effect of the present invention can be more effectively exerted. The pH of the polishing composition according to the present invention is preferably 2.0 or more and 4.0 or less, more preferably 2.5 or more and 3.5 or less, and further preferably 2.7 or more and 3.2 or less. If the pH is within the above range, where the anion-modified colloidal silica is used as the abrasive grains, the anion-modified colloidal silica has negative zeta potential, and, therefore, may be excellent in dispersion stability, which is an advantage of the anion-modified colloidal silica.

The polishing composition according to the present invention may contain a pH adjusting agent in order to adjust the pH of the polishing composition. As the pH adjusting agent, one type thereof may be used alone, or two or more types thereof may be used in combination. As the pH adjusting agent, a commercially available product may be used, or a synthesized product may be used.

The pH adjusting agent is not particularly limited, and known pH adjusting agents used in the field of polishing compositions can be used. As the pH adjusting agent, known acids, bases, salts thereof, or the like can be used. Examples of the pH adjusting agent include organic acids such as carboxylic acids such as formic acid, acetic acid, propionic acid, butyric acid, valeric acid, caproic acid, enanthic acid, caprylic acid, pelargonic acid, capric acid, lauric acid, myristic acid, palmitic acid, margaric acid, stearic acid, oleic acid, linoleic acid, linolenic acid, arachidonic acid, docosahexaenoic acid, eicosapentaenoic acid, lactic acid, malic acid, citric acid, benzoic acid, phthalic acid, isophthalic acid, terephthalic acid, salicylic acid, gallic acid, mellitic acid, cinnamic acid, oxalic acid, malonic acid, succinic acid, glutaric acid, adipic acid, fumaric acid, maleic acid, aconitic acid, amino acid, and anthranilic acid, sulfonic acid, and organic phosphonic acid; inorganic acids such as nitric acid, carbonic acid, hydrochloric acid, hypophosphorous acid, phosphorous acid, phosphonic acid, boric acid, and hydrofluoric acid; hydroxides of alkali metals such as potassium hydroxide (KOH); carbonates of alkali metals such as potassium carbonate (K₂CO₃) and sodium carbonate (Na₂CO₃); hydroxides of group 2 elements; ammonia (ammonium hydroxide); and organic bases such as quaternary ammonium hydroxide compounds.

The content (concentration) of the pH adjusting agent in the polishing composition may be appropriately selected so that the polishing composition has a desired value of pH.

For the pH in the polishing composition, a value obtained by measurement by the method described in Examples is adopted.

### [Dispersing Medium]

The polishing composition according to the present invention may contain a dispersing medium in order to dissolve and/or disperse each component. As the dispersing medium, one type thereof may be used alone, or two or more types thereof may be used in combination.

The dispersing medium is not particularly limited, and examples thereof include water; alcohols such as methanol, ethanol, and ethylene glycol; ketones such as acetone; and mixtures thereof. The dispersing medium is preferably water.

The water is preferably water containing as few impurities as possible from the viewpoint of preventing the impurities from inhibiting the function of the component contained in the polishing composition. The water is preferably water in which the total content of transition metal ions is 100 ppb or less. The purity of the water can be enhanced by operations such as removing impurity ions by using an ion exchange resin, removing foreign matter with a filter, or distillation. The water is more preferably selected from deionized water (ion exchange water), pure water, ultrapure water, and distilled water.

### [Other Components]

The polishing composition according to the present invention may further contain other known components that may be used for the polishing composition to an extent that the effect of the present invention is not inhibited. Examples of other components include oxidizing agents, antifungal agents (antiseptic agents), complexing agents, and metal anticorrosives. Hereinafter, the oxidizing agents, and the antifungal agents (antiseptic agents) will be described.

Examples of the oxidizing agent include hydrogen peroxide, sodium peroxide, barium peroxide, ozonated water, silver (II) salts, iron (III) salts, permanganic acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, chlorous acid, perchloric acid, bromic acid, iodic acid, periodic acid, persulfuric acid, dichloroisocyanuric acid, and salts thereof (such as potassium salts, sodium salts, and ammonium salts). As the oxidizing agent, one type thereof may be used alone, or two or more types thereof may be used in combination.

Examples of the antifungal agent (antiseptic agent) include isothiazoline antiseptic agents such as 2-methyl-4-isothiazolin-3-one and 5-chloro-2-methyl-4-isothiazolin-3-one; and phenoxyethanol. As the antifungal agent (antiseptic agent), one type thereof may be used alone, or two or more types thereof may be used in combination.

In an embodiment, the polishing composition according to the present invention may be a one-pack type or a multi-pack type such as a two-pack type.

### [Method for Producing Polishing Composition]

The method for producing the polishing composition according to the present invention is not particularly limited, and the polishing composition can be obtained by, for example, stirring and mixing the abrasive grains and the nonionic surfactant, and, as necessary, the pH adjusting agent, the dispersing medium, and other components together. Details of each component are as described above.

The temperature at the time of mixing each of the components together is not particularly limited, and is preferably 10° C. or more and 40° C. or less, and the components may be heated in order to increase the rate of dissolution. Also, the mixing time is not particularly limited as long as homogeneous mixing can be performed.

### <Polishing Method and Method for Producing Semiconductor Substrate>

An aspect of the present invention relates to a polishing method including a step of polishing an object to be polished containing a carbon film by using the polishing composition as described above.

An aspect of the present invention relates to a method for producing a semiconductor substrate including a step of polishing a semiconductor substrate containing a carbon film by the polishing method as described above.

The polishing apparatus is not particularly limited, and, for example, a common polishing apparatus having a holder for holding a substrate or the like containing the object to be polished, a motor in which the rotation speed can be changed, and the like provided therein, and having a polishing table to which a polishing pad (polishing cloth) can be sticked can be used as the polishing apparatus.

The polishing pad is not particularly limited, but, for example, common nonwoven fabric, polyurethane, or porous fluororesin can be used as the polishing pad without particular limitation. It is preferred that the polishing pad has been subjected to grooving so that polishing liquid is stored.

The polishing conditions are not particularly limited. For example, with regard to the polishing table and the rotation speed of the head, 10 rpm (0.17 s⁻¹) or more and 500 rpm (8.33 s⁻¹) or less is preferred. For example, the pressure to be applied to the substrate having the object to be polished (polishing pressure) is preferably 0.5 psi (3.4 kPa) or more and 10 psi (68.9 kPa) or less.

The method for supplying the polishing composition to the polishing pad is not particularly limited as well, and, for example, a method in which the polishing composition is continuously supplied with a pump or the like is adopted. The supply amount is not limited, but it is preferred that the surface of the polishing pad is covered with the polishing composition at all times. The polishing time is not particularly limited as well, and, for example, appropriately selecting the time such that desired polishing can be achieved is sufficient.

After finishing polishing, the substrate or the like containing the object to be polished may be washed in running water, and then water droplets adhered to the substrate may be removed to dry the substrate by using a spin dryer or the like.

The polishing composition according to the present invention may be a one-pack type or a multi-pack type such as a two-pack type. The polishing composition according to the present invention may be prepared by diluting the stock solution of the polishing composition to, for example, 3 times or more (or, for example, 5 times or more) by using a diluting liquid such as water.

### [Polishing Removal Rate of Carbon Film]

The polishing composition according to the present invention can polish the carbon film at a high polishing removal rate.

In the present invention, the lower limit of the polishing removal rate of the carbon film is, for example, 80 Å/min or more, and is preferably 90 Å/min or more, more preferably 140 Å/min or more, and further preferably 180 Å/min or more.

Embodiments of the present invention are described above in detail, but the description is merely illustrative and exemplary and is not limitative. It is clear that the scope of the present invention should be interpreted based on the attached claims.

The present invention encompasses the following aspects and embodiments.
[1] A polishing composition containing abrasive grains and a nonionic surfactant, wherein the polishing composition is used for polishing an object to be polished containing a carbon film.
[2] The polishing composition according to the [1], wherein the nonionic surfactant contains a compound having a polyoxyalkylene glycol structure.
[3] The polishing composition according to the [1] or the [2], wherein the nonionic surfactant contains a compound represented by the following formula 1.

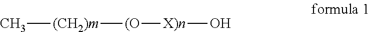

Wherein X is an alkylene group having 2 or 3 carbon atoms; m is an integer of 4 or more and 14 or less; and n is an integer of 3 or more and 25 or less.
[4] The polishing composition according to the [3], wherein, in the formula 1, X is an ethylene group; m is 7 or more and 9 or less; and n is 5 or more and 10 or less.
[5] The polishing composition according to any of the [1] to the [4], wherein a content of the nonionic surfactant is 0.01 mass % or more and 0.1 mass % or less based on a total mass of the polishing composition.
[6] The polishing composition according to any of the [1] to the [5], wherein the abrasive grains contain a colloidal silica.
[7] The polishing composition according to any of the [1] to the [6], wherein the abrasive grains contain an anion-modified colloidal silica.
[8] The polishing composition according to any of the [1] to the [7], wherein the composition has a pH of 1.0 or more and 5.0 or less.
[9] A polishing method comprising a step of polishing an object to be polished containing a carbon film by using the polishing composition according to any one of the [1] to the [8].

A method for producing a semiconductor substrate comprising a step of polishing a semiconductor substrate containing a carbon film by the polishing method according to the [9].

### EXAMPLES

The present invention will be described in more detail with reference to the following Examples and Comparative Example. The technical scope of the present invention is not limited to the following Examples. Unless otherwise specified, “%” and “parts” mean “mass %” and “parts by mass”, respectively. Also, unless otherwise specified, operations were performed under the conditions of room temperature (20° C. or more and 25° C. or less)/a relative humidity of 40% RH or more and 50% RH or less.

### <Measurement Method>

### (Average Primary Particle Size of Abrasive Grain)

The average primary particle size of the abrasive grain was calculated from the specific surface area of the abrasive grain measured by using “Flow Sorb II 2300” manufactured by Micromeritics Instrument Corporation by BET method and the density of the abrasive grain.

### (Average Secondary Particle Size of Abrasive Grain)

The average secondary particle size of the abrasive grain was measured as a volume-average particle size (arithmetic mean size on volume basis; Mv) by using a dynamic light scattering particle size and particle size distribution measurement apparatus UPA-UT151 (manufactured by NIKKISO CO., LTD.)

### (pH of Polishing Composition)

With regard to the pH of the polishing composition, by using a glass electrode type hydrogen ion concentration indicator (manufactured by HORIBA, Ltd.; model: F-23), three-point calibration was performed by using standard buffer solutions (a phthalate pH buffer solution having a pH of 4.01 (25° C.), a neutral phosphate pH buffer solution having a pH of 6.86 (25° C.), and a carbonate pH buffer solution having a pH of 10.01 (25° C.)), and then the glass electrode was placed in the polishing composition for 2 minutes or more to allow the pH value to become stable. The pH value after the value became stable was defined as the pH value of the polishing composition.

### Comparative Example 1

A sulfonic acid-modified colloidal silica (average primary particle size: 15 nm; average secondary particle size: 34 nm) as abrasive grains was added to pure water as a dispersing medium so that the final concentration would be 0.4 mass %. Thereafter, nitric acid was added thereto so that the pH would be 2.8 to prepare a polishing composition.

### Example 1

A sulfonic acid-modified colloidal silica (average primary particle size: 15 nm; average secondary particle size: 34 nm) as abrasive grains was added to pure water as a dispersing medium so that the final concentration would be 0.4 mass %. Further, polyoxyethylene (10) monodecyl ether as a nonionic surfactant was added thereto so that the final concentration would be 0.04 mass %. Then, the resulting solution was stirred and mixed for 30 minutes at room temperature (25° C.). Thereafter, nitric acid was added thereto so that the pH would be 2.9 to prepare a polishing composition.

### Examples 2 to 3

A polishing composition was prepared in the same manner as in Example 1 except that the concentration of the nonionic surfactant was changed as described in Table 1 below.

### Example 4

A sulfonic acid-modified colloidal silica (average primary particle size: 15 nm; average secondary particle size: 34 nm) as abrasive grains was added to pure water as a dispersing medium so that the final concentration would be 0.4 mass %. Further, polyoxyethylene (5) monodecyl ether as a nonionic surfactant was added thereto so that the final concentration would be 0.02 mass %, and then the resulting solution was stirred and mixed for 30 minutes at room temperature (25° C.). Thereafter, nitric acid was added thereto so that the pH would be 2.8 to prepare a polishing composition.

### Example 5

A polishing composition was prepared in the same manner as in Example 4 except that the concentration of the nonionic surfactant was changed as described in Table 1 below.

### Example 6

A sulfonic acid-modified colloidal silica (average primary particle size: 15 nm; average secondary particle size: 34 nm) as abrasive grains was added to pure water as a dispersing medium so that the final concentration would be 0.4 mass %. Further, polyoxyethylene (7) monooctyl ether as a nonionic surfactant was added thereto so that the final concentration would be 0.06 mass %, and then the resulting solution was stirred and mixed for 30 minutes at room temperature (25° C.). Thereafter, nitric acid was added thereto so that the pH would be 2.8 to prepare a polishing composition.

### Example 7

A polishing composition was prepared in the same manner as in Example 6 except that the concentration of the nonionic surfactant and the pH of the polishing composition were changed as described in Table 1 below.

The constitution of each polishing composition is shown in Table 1. In Table 1, “-” indicates that the component was not used.

### <Evaluation>

The surface of the object to be polished was polished under the following conditions by using each polishing composition prepared in the above manner. As the object to be polished, a silicon wafer having a spin-on carbon (SoC) film having a thickness of 2,000 Å formed on the surface thereof (manufactured by Advanced Materials Technology, Inc.; 300 mm; blanket wafer) was used.

### (Polishing Apparatus and Polishing Conditions)

Polishing apparatus: Polishing apparatus manufactured by EBARA CORPORATION (model: FREX 300E)
Polishing pad: Suede pad manufactured by NITTA DuPont Incorporated; Supreme RN-H
Polishing pressure: 1.5 psi (1 psi=6894.76 Pa)
Conditioner (dresser): Nylon brush manufactured by 3M Company
Rotation speed of polishing table: 40 rpm
Rotation speed of head: 40 rpm
Supply of polishing composition: continuous supply
Supply amount of polishing composition: 200 mL/minute
Polishing time: 30 seconds

### (Evaluation of Polishing Removal Rate)

The thicknesses before and after polishing of the SoC film were determined with an optical film thickness measurement apparatus (ASET-f5x: manufactured by KLA Corporation). Based on the determined thicknesses, [(Thickness before polishing [unit: Å])−(Thickness after polishing [unit: Å])] was divided by the polishing time [unit: min] to calculate the polishing removal rate [unit: Å/min] for object to be polished. In the present invention, if the polishing removal rate for the SoC film is 80 Å/min or more, the SoC film can be practically used.

The result of evaluation of the polishing removal rate is shown in Table 1.

TABLE 1

| | | Nonionic | | Polishing removal |
|---|---|---|---|---|
| | Abrasive grains | surfactant | | rate of SoC film |
| | [mass %] | [mass %] | pH | [Å/min] |
| Comparative | 0.4 | — | 2.8 | 74 |
| Example 1 | | | | |
| Example 1 | 0.4 | 0.04 | 2.9 | 183 |
| Example 2 | 0.4 | 0.06 | 2.9 | 189 |
| Example 3 | 0.4 | 0.08 | 2.9 | 251 |
| Example 4 | 0.4 | 0.02 | 2.8 | 145 |
| Example 5 | 0.4 | 0.08 | 2.8 | 386 |
| Example 6 | 0.4 | 0.06 | 2.8 | 93 |
| Example 7 | 0.4 | 0.08 | 2.9 | 96 |

As is clear from Table 1, it is shown that, where the polishing compositions according to Examples are used, the SoC film can be polished at a high polishing removal rate compared with the case where the polishing composition according to Comparative Example is used.

The present application is based on Japanese Patent Application No. 2024-168525, filed on Sep. 27, 2024, the entire contents of which being herein incorporated by reference.

1. A polishing composition comprising abrasive grains and a nonionic surfactant,
wherein the polishing composition is used for polishing an object to be polished containing a carbon film.

2. The polishing composition according to claim 1, wherein the nonionic surfactant comprises a compound having a polyoxyalkylene glycol structure.

3. The polishing composition according to claim 2, wherein the nonionic surfactant comprises a compound represented by the following formula 1: 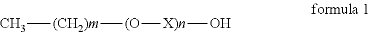
wherein X is an alkylene group having 2 or 3 carbon atoms; m is an integer of 4 or more and 14 or less; and n is an integer of 3 or more and 25 or less.

4. The polishing composition according to claim 3, wherein, in the formula 1, X is an ethylene group; m is 7 or more and 9 or less; and n is 5 or more and 10 or less.

5. The polishing composition according to claim 1, wherein a content of the nonionic surfactant is 0.01 mass % or more and 0.1 mass % or less based on a total mass of the polishing composition.

6. The polishing composition according to claim 1, wherein the abrasive grains comprise a colloidal silica.

7. The polishing composition according to claim 1, wherein the abrasive grains comprise an anion-modified colloidal silica.

8. The polishing composition according to claim 1, wherein the composition has a pH of 1.0 or more and 5.0 or less.

9. A polishing method, comprising polishing an object to be polished containing a carbon film by using the polishing composition according to claim 1.

10. A method for producing a semiconductor substrate, comprising polishing a semiconductor substrate containing a carbon film by the polishing method according to claim 9.
